(19) United States
(12) Patent Application Publication
(10) Pub. No.: US 2014/0077856 A1
(43) Pub. Date: Mar. 20, 2014

(54) INTEGRATED CIRCUIT DEVICE AND METHOD FOR SELF-HEATING AN INTEGRATED CIRCUIT DEVICE

(71) Applicants: Sergey Sofer, Rishon Lezion (IL); Moty Groissman, Beer Sheba (IL); Eyal Melamed-Kohen, Modiin (IL); Naom Sivam, Ganey Tikva (IL)

(72) Inventors: Sergey Sofer, Rishon Lezion (IL); Moty Groissman, Beer Sheba (IL); Eyal Melamed-Kohen, Modiin (IL); Naom Sivam, Ganey Tikva (IL)

(73) Assignee: Freescale Semiconduction, Inc., Austin, TX (US)

(21) Appl. No.: 14/115,710

(22) PCT Filed: May 27, 2011
(86) PCT No.: PCT/IB2011/052329

§ 371 Date: Nov. 5, 2013

(51) Int. Cl. H03K 3/011

(52) U.S. Cl. CPC H03K 3/011
USPC 327/219

(57) ABSTRACT

An integrated circuit device comprises a first clock signal source, arranged to provide at least one first clock signal; a second clock signal source, arranged to provide at least one second clock signal different from the at least one first clock signal; and a plurality of sequential logic cells, at least one of the plurality connected to receive, in a first mode, the at least one first clock signal or at least one clock signal derived from the at least one first clock signal, and to receive, in a second mode, the at least one second clock signal or at least one clock signal derived from the at least one second clock signal; wherein in the second mode the at least one second clock signal is adapted to the at least one of the plurality of sequential logic cells to generate in at least a portion of the integrated circuit device a current consumption when the at least one first clock signal is not a toggling signal.

### FIELD OF THE INVENTION

This invention relates to an integrated circuit device and a method for self-heating an integrated circuit device.

### BACKGROUND OF THE INVENTION

Integrated circuit (IC) devices, i.e., semiconductor devices comprising at least one integrated circuit, are usually operated in a preferred operational range, which may be determined by parameters such as, for example, the temperature of the device. For example, the behaviour of an integrated circuit device may be influenced by the temperature-dependency of the switching speed of transistors, such as a metal-oxide-semiconductor field-effect transistors (MOSFET), contained in the integrated circuit.

Due to an ongoing miniaturization in semiconductor manufacturing technology the impact of temperature on MOSFET switching characteristics has changed, since the weighting of different parameters, each being temperature dependent, changes with transistor size. For example, MOSFET created using lithographic processes in the micrometer-range, may exhibit a switching delay that increases with temperature, whereas MOSFET created using more modern processes, for example, in the nanometer-range, such as 65 nm, 45 nm, 32 nm, 28 nm, or 22 nm processes, may encounter a temperature inversion effect, causing the switching delay to decrease with increasing temperature. The temperature inversion effect appears when the electrical signal paths are “slower” at cold temperature than at hot temperature due to a combination of temperature-dependent MOSFET parameters. A conjunction of the following parameters, each depending on temperature T and influencing the transistor switching delay differently, may cause the temperature inversion effect: the charge carrier mobility, which is a function of T⁻² at gate bias, corresponding to strong inversion; the transistor threshold voltage Vₜₕ, which is a function of T⁻¹; and the sub-threshold or leakage current, which is a function of T.

In U.S. Pat. No. 7,773,446 B2, a method and apparatus for extending the effective thermal operating range of a non-volatile memory IC is shown. A thermal sensor is used to permanently sense a temperature of the IC and an active resistive heating element is used for heating the memory IC, if a sensed temperature is below a threshold temperature.

In U.S. Pat. No. 6,815,643 B2, a semiconductor device with temperature regulation is shown, in which an integrated circuit additionally contains a thermal diode for temperature measurement and a dedicated ring structure for heating up itself and thereby indirectly the rest of the semiconductor device, i.e. a dedicated oscillator executes dummy cycles in order to generate heat.

### SUMMARY OF THE INVENTION

The present invention provides an integrated circuit device and method for self-heating an integrated circuit device as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIG. 1 schematically shows an example of a first embodiment of an integrated circuit device.

FIG. 2 schematically shows an example of a master-slave flip-flop circuit with an unprotected reset input.

FIG. 3 schematically shows an example of a second embodiment of an integrated circuit device.

FIG. 4 schematically shows a diagram of an example of an embodiment of a method for self-heating an integrated circuit device.

### DETAILED DESCRIPTION OF THE PREFERRED EMBODIMENTS

Because the illustrated embodiments of the present invention may for the most part, be implemented using electronic components and circuits known to those skilled in the art, details will not be explained in any greater extent than that considered necessary, as illustrated, for the understanding and appreciation of the underlying concepts of the present invention and in order not to obfuscate or distract from the teachings of the present invention.

When developing an integrated circuit, the FET junction temperature range required for assuring correct behaviour of the transistor may be reduced, allowing faster and easier design closure, by taking into account the device self-heating. The design closure may be faster due to narrower spread of parameters. The presented device may allow eliminating the slowest design corner during the design closure and thus may decrease design complexity and design closure effort, followed by saving silicon area and decreasing the power consumption.

During the start-up (power-up- and boot-phase) the die carrying the integrated circuit may still be cold and the on-die circuits may be “slow”, providing a long switching delay, when considering the temperature inversion effect. Regardless of the abovementioned self-heating, this may force the IC designer not using the presented approach to make the closure at low temperature. The shown integrated circuit device may instead allow to decrease design complexity and may allow easier closure.

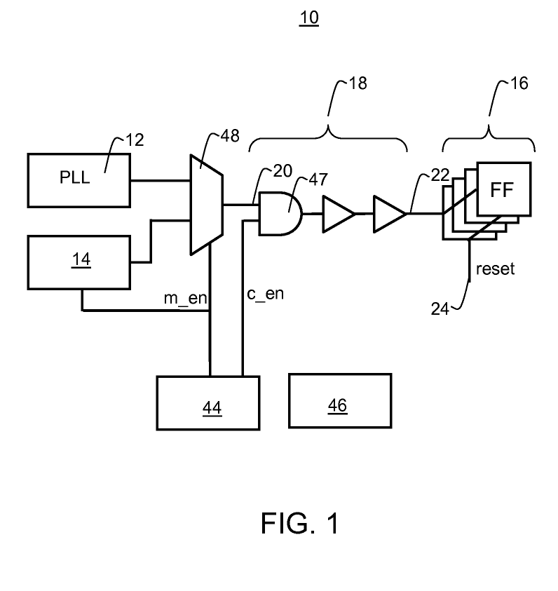

Referring to FIG. 1, an example of a first embodiment of an integrated circuit device 10 is schematically shown. The integrated circuit device 10 comprises a first clock signal source 12, arranged to provide at least one first clock signal; a second clock signal source 14, arranged to provide at least one second clock signal; and a plurality of sequential logic cells 16, at least one of the plurality connected to receive, in a first mode, the at least one first clock signal or at least one clock signal derived from the at least one first clock signal, and to receive, in a second mode, the at least one second clock signal or at least one clock signal derived from the at least one second clock signal; wherein in the second mode the at least one second clock signal is adapted to the at least one of the plurality of sequential logic cells to generate in at least a portion of the integrated circuit device a current consumption when the at least one first clock signal is not a toggling signal.

The integrated circuit device temperature, and thereby e.g., the junction temperature of MOSFETs of the integrated circuit, may depend on an may be regulated by the current- or power consumption in at least the portion of the integrated circuit device that is arranged to consume current for self-heating purposes when one or more, e.g. all, of the sequential logic cells 16 receive in the second mode the second clock signal.

The shown integrated circuit device having a second or self-heating mode may allow to utilize existing on-die circuits for heating purpose, avoiding a need for dedicated heating devices.

The integrated circuit device may be switched to the self-heating mode or second mode of operation at any time. For example, it may be switched to the second mode for self-heating the device before the device functional operation starts after or within start up and boot phase. During at least a part of the duration of the start up and boot phase, at least one of the first clock signals may be a steady-state signal, i.e., not a toggling or oscillating signal, but a signal being constantly at one signal level, such as “high” or “low” or “1” or “0”. This may be the case when, during start up of the integrated circuit device, the first clock signal source, which may be the primary clock signal source, may not be available for provision of a toggling signal yet.

A signal may be a change of a physical quantity carrying information, for example a change of a voltage level. In electronics, especially synchronous digital circuits, a clock signal may be a particular type of signal that oscillates or toggles between a high and a low state and may be used to trigger actions of the circuits. For example, a transition from a low state to a high state may be characterized by a rising edge of the clock signal and a transition from a high state to a low state may be characterized by a falling edge of the respective clock signal. In other embodiments, for example, inverse definitions of state transitions may apply. A signal that does not oscillate between high and low state but remains in one of the states may be referred to as a steady-state signal when applied to a clock signal input of a circuit.

A sequential logic cell may be a logic circuit wherein the output signal depends not only on the current input signal but also on the history of the input signal. A sequential logic cell may, for example, be a flip-flop circuit or a latch or a circuit comprising more than one flip-flop. A sequential logic cell may be considered a synchronous digital circuit or synchronous logic cell, when internal state changes of the cell only occur, for example, on a clock edge of a received clock signal.

A clock signal source may, for example, be one or more oscillator circuits, e.g., located on the same die, or an interface connected to one or more external oscillator circuits. The first clock signal source may, for example, comprise a local oscillator arranged to provide a standard or normal operation clock signal. The first clock signal source may, for example, comprise a phase-locked loop circuit containing a local oscillator.

The at least one second clock signal may be different from the at least one first clock signal if, for example, at least some of first and second clock rates, i.e., clock frequencies, are different.

Depending on the current mode, at least one of the sequential logic cells may receive either a first or a second clock signal or a clock signal derived from that particular signal. The latter may, for example, apply when the connection between clock signal source and sequential logic cells is an indirect connection, i.e., comprising circuitry to generate derived clock signals, for example, by frequency division of the clock signal received by the particular clock signal source.

The first mode may be a normal operation mode, which may include a start-up and boot phase and a normal processing phase. The integrated circuit device may be any device comprising sequential logic. It may, for example, be a processing device, such as a microcontroller, a microprocessor, a graphics processor, a digital signal processor, just to name a few.

While the first mode may be considered the normal operation mode, the second mode may be regarded as a self-heating mode, i.e. wherein the integrated circuit device is arranged to increase its temperature by generating heat without applying additional circuits added to the device especially for the purpose of dissipating heat. Current flow through a resistive circuit may cause current consumption resulting in heat dissipation. The presented integrated circuit device may be arranged to provide a second mode, when providing the first or normal operation mode is not possible, which may be the case during a start-up phase of the integrated circuit device. Depending on the circuit features of the at least one of the plurality of sequential logic cells, that is arranged to receive the second clock signal, or a clock signal derived from the second clock signal, the second clock signal may be arranged to cause increased current consumption within a portion or all of the integrated circuit device. For example, the portion of the integrated circuit device may comprise the at least one of the plurality of sequential logic cells, i.e., the sequential logic cell(s) themselves may consume current and dissipate heat while receiving the second clock signal, e.g., due to clock-reset contention or state changes during the second mode, although no toggling first clock signal may be available.

The integrated circuit device 10 may comprise a clock distribution network having at least one input terminal 20 connected to the first and second clock signal sources 12, 14, and at least one output terminal 22 connected to the plurality of sequential logic cells 16. The clock distribution network 18 may be arranged to receive the at least one first clock signal in the first mode and the at least one second clock signal in the second mode and to provide the at least one first clock signal or the at least one clock signal derived from the at least one first clock signal in the first mode, and to provide the at least one second clock signal or the at least one clock signal derived from the at least one second clock signal in the second mode. The clock distribution network may distribute the first or second clock signals to all the sequential logic cells 16. It may, for example, be arranged to either provide the received clock signal to each connected cell or to provide one or more derived clock signals generated, e.g., by clock signal division, from the received clock signals. The clock signal network may, for example, form a clock tree having sequential logic cells or sequential circuits, such as flip-flop circuits or synchronous random access memory (RAM) units connected to its leafs. In the shown integrated circuit device 10 comprising the clock distribution network 18, the portion of the integrated circuit device wherein a current consumption may be generated in the second mode even when the first clock signal is not a toggling signal, may comprise at least a part the clock distribution network 18.

The integrated circuit device temperature, and thereby, e.g., the junction temperature of MOSFETs of the integrated circuit, may depend on and may be regulated by the current- or power consumption of the sequential logic cells 16 and of the clock distribution network 18 components. Since a clock distribution network or clock network 18 may sometimes consume about 50% of an average dynamic power consumption of a chip, an increased current consumption and thereby power consumption may effectively increase and speed up self-heating of the device 10.

A set/reset driver may be used in at least one of the stages of the sequential logic cells 16. The at least one of the plurality of sequential logic cells 16 of the integrated circuit device 10 shown in FIG. 1 may comprise a reset-input 24 arranged to receive a reset signal (reset); and the reset signal may be enabled when the integrated circuit device 10 is in the second mode. A reset may bring the sequential logic cell to normal condition or initial state in a controlled manner. Reset may be synchronous, i.e., synchronized with the clock signal, and asynchronous, i.e., brought to the circuit with no reference to the clock signal state.

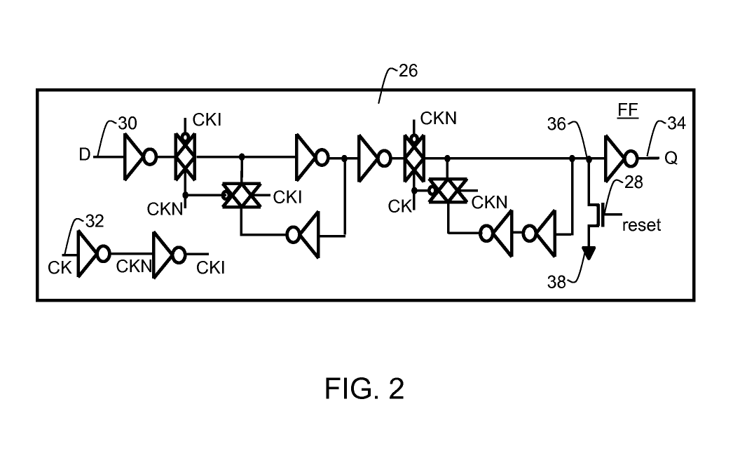

Referring to FIG. 2, an example of a master-slave (MS) flip-flop circuit 26 with an unprotected reset input is schematically shown as an example for a sequential logic cell having a reset input. An application of a reset signal (reset) to a gate of a field-effect transistor 28 of the shown D-type MS-flip-flop circuit 26, which comprises, besides the reset input and clocked gates and inverter circuits for implementing the master-slave flip-flop functionality, a data D input terminal 30, a clock CK input terminal 32, and a Q output terminal 34. The shown reset signal input may be arranged to allow an unprotected reset, i.e., may allow to connect the node 36 to ground 38 independently of the current signal levels received at data D input 30 and clock CK input 32. This may create contention at node 36, if the data signal D level is high, each time the clock signal is set to high, allowing a short circuit current to flow through node 36. This may generate increased current consumption and heat dissipation at least in the shown flip-flop circuit 26.

In the second mode, the at least one second clock signal may, for example, be adapted to the at least one of the plurality of sequential logic cells to generate in at least a portion of the integrated circuit device a higher current consumption rate than in the first mode by adjusting the clock rate of at least one second clock signal to have the sequential logic cells consume more current by application of trigger events to the clock distribution network and sequential cells, or by applying a constant steady-state signal to at least one of the sequential logic cells.

In case of a reset enable signal applied to at least one of the sequential logic cells 16, thereby periodically generating a clock-and-reset contention each time the second clock signal changes to high level, current consumption and heat dissipation may be increased. In an embodiment, a clock rate of at least one second clock signal may, for example, be higher than a clock rate of the at least one first clock signal in order to generate more state changes and more current consumption of the integrated circuit device 10. This may include that the first clock signal does not toggle its state or level, e.g., because the first clock signal source is currently not available for clock signal toggling.

Referring to FIG. 1, the second clock source 14 may, for example, comprise a first ring oscillator circuit for providing the second clock signal. A ring oscillator may, for example, be a circuit composed of an odd number of inverting circuits connected in a chain, wherein an output of the last inverter is fed back to an input of the first inverter of the chain. A ring oscillator may consist of only a few, e.g. 3 or 5 inverting circuits and may be added to the IC using only very little additional die area.

The second clock signal source 14 may, for example, be different from the first clock signal source 12. Requirements concerning parameters such as stability of the produced clock signal frequency maybe low for the second or self-heating clock signal and, for example, during start-up phase of the device, the simply structured second clock source may be available faster and may consume less power by itself than the first clock signal source 12, which may, for example, be a PLL clock source. In another embodiment of the integrated circuit device 10, for example, where the first clock source is available fast and intended to be used also for heating, the second signal source 14 may be the first signal source 12, e.g. a PLL circuit, supplied with different parameter settings in order to generate a second clock signal different from the first clock signal, for example, having a different clock frequency or clock rate or other clock characteristic such as different clock jitter.

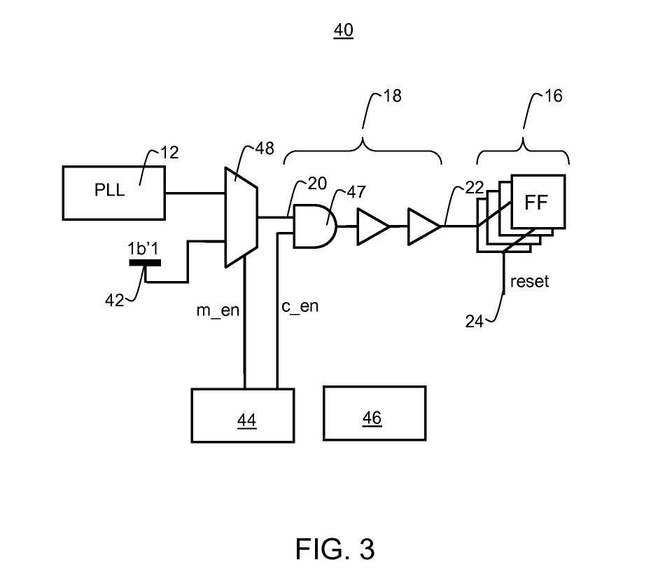

Referring to FIG. 3, an example of a second embodiment of an integrated circuit device is schematically shown. The structure of the shown second embodiment 40 is similar to the first embodiment 10 shown in FIG. 1 and only elements differing from the integrated circuit device 10 shown in FIG. 1 will be described.

For the integrated circuit device 40, the at least one second clock signal may be a steady-state signal. The steady-state signal may not toggle and may, for example, be a signal being constantly at logic level “high” or “1” (1b′1). This may, for example, be achieved by providing the second clock signal source 42 as a connection to the voltage supply of the device. The self-heating process may always occur when in second mode. It may especially be effective in the second mode, when applying a reset enable signal to one, more than one or all of the sequential logic cells 16 while being connected to the steady-state clock signal source 42, since this may create clock-and-reset contention within the sequential logic cells during the whole time the cells receive the reset enable signal while in second mode. In the example shown in FIG. 2, clock-and-reset contention may, for example, occur at node 36. The added on-die logic may force logic level “1” to the sequential logic cells 16, e.g., through the clock network 18, especially during reset, which may be the Power On Reset (PoR), and may thereby cause clock-and-reset contention in all or a part of the sequential logic cells 16 for some period of time, e.g., several hundreds of clock cycles, with parallel fast and coarse temperature sensing.

In another embodiment of the integrated circuit device, the second clock source 14, 42 may be arranged to provide a steady-state clock signal and a second clock signal oscillating at a certain frequency. The selection, which type of second clock signal is to be provided at a time during the second mode may depend on a received information, for example the temperature of the integrated circuit device or whether or not the reset signal is set to enabled.

Referring to FIG. 1 and to FIG. 2, the integrated circuit device 10, 40 may comprise a temperature sensing unit 46 arranged to provide a temperature measurement of the integrated circuit device 10, 40; and a mode controller unit 44 arranged to switch the integrated circuit device 10, 40 from the second mode into the first mode when a value of the temperature measurement is above a threshold value corresponding to a minimum normal operation temperature. The integrated circuit device 10, 40 may, for example, comprise a multiplexer unit 48 arranged to connect, depending on a selection signal m_en, either the first clock signal source 12 or the second clock signal source 14, 42 to the sequential logic cells 16, for example, through the clock distribution network 18. The selection signal m_en may be set by the mode controller unit 44. m_en may be set to enable the connection to the first clock signal source 12, if the measured temperature is detected to be above the threshold temperature, and to enable the connection to the second clock signal source 14, 42, if the measured temperature is detected to be below the threshold temperature. The selection signal m_en may, for example, also be arranged to switch off or disable the second clock signal source 14 during the first mode of operation. This may, for example, allow to save power.

In another embodiment, no multiplexer unit 48 may be used. Instead, the mode controller unit 44 may be arranged to directly switch on and off the first and second clock signal sources, depending on the selected mode.

The minimum normal operation temperature may, for example, be defined to at least partly compensate for a switching delay caused by a temperature inversion effect encountered at one or more field-effect transistor circuits comprised in the plurality of sequential logic cells 16. The threshold value may, for example, be selected depending on the transistor sizes, which may depend on the manufacturing process. It may be pre-defined and set, for example, to 0° C. or 10° C., e.g. for 65 nm-technology or 28 nm-technology. The presented device may allow temperature inversion compensation, e.g. during a boot phase. The device may allow narrowing the chip temperature range based on the self-heating.

The integrated circuit device may, for example, comprise a gate 47 for enabling or disabling the provision of any clock signal to the rest of the integrated circuit device, depending on a clock enable signal c_en, which may enable provision of a clock signal, if reset is enabled or if m_en is set to enable provision of the second clock signal.

Since the integrated circuit device 10, 40 may most likely be cold when starting up the device at cold ambient temperature, it may be initially started in second mode. Or the mode controller unit 44 may be arranged to switch the integrated circuit device from the first mode into the second mode when a value of the temperature measurement is below the threshold value. This may allow to apply the second self-heating mode not only during the start phase, but at any time necessary, e.g., when operating the integrated circuit device 10, 40 in a very cold environment or in case the ambient temperature rapidly changes and cools down the integrated circuit device 10, 40 during first or normal operation mode.

The integrated circuit device may be operated in the second mode for any period of time. Often, this period may be short, e.g. some hundreds of clock cycles for fast self-heating before switching to normal operation mode. The duration of the second mode may, for example, be dependent on the temperature measurement. For example, the difference between the measured temperature and the threshold value may be used for determining the duration of the self-heating.

The temperature measurement may be fast and may be coarse, for example, providing an accuracy resolution of, e.g., 10° C. The thermal sensor or temperature sensing unit 46 may be simple and may, for example, comprise a second ring oscillator circuit. In yet another embodiment, the first ring oscillator circuit and the second ring oscillator circuit may be the same oscillator circuit, i.e., the second clock source may also be used for providing the temperature measurement. Here, an initial calibration of this circuit may be carried out to preset dependency between the ring oscillator speed and the circuit junction temperature.

The integrated circuit device 10, 40 may, for example, be provided as a single-chip package. This may allow for a very efficient self-heating of the device.

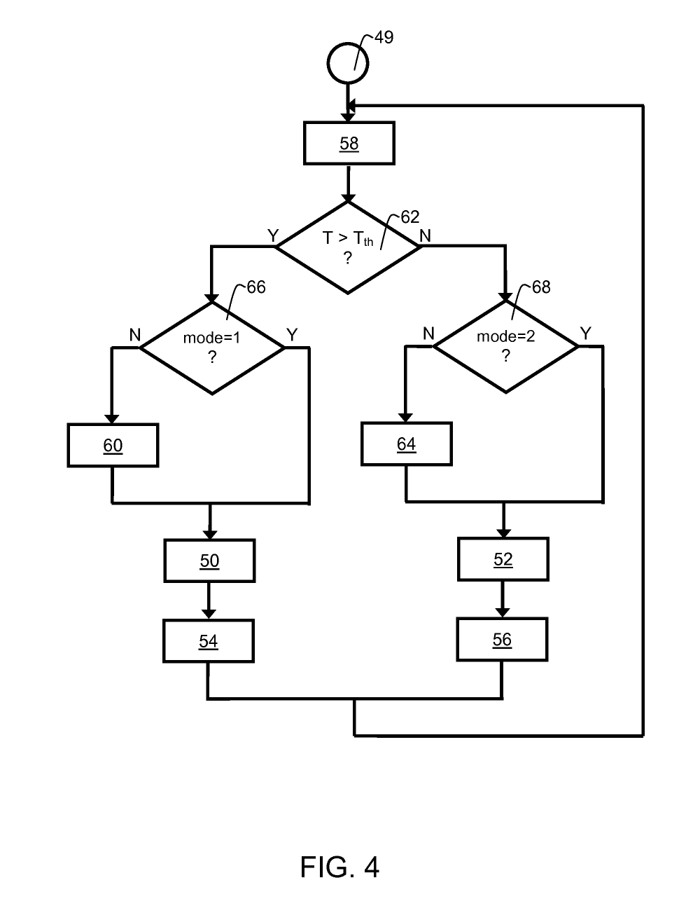

Referring now to FIG. 4, a diagram of an example of an embodiment of a method for self-heating an integrated circuit device is schematically shown. The illustrated method allows implementing the advantages and characteristics of the described integrated circuit device as part of a method for self-heating of an integrated circuit device.

The method for self-heating an integrated circuit device may comprise providing 50 at least one first clock signal, by a first clock signal source; providing 52 at least one second clock signal; receiving 54, in a first mode, the at least one first clock signal or at least one clock signal derived from the at least one first clock signal, by at least one of a plurality of sequential logic cells; and receiving 56, in a second mode, the at least one second clock signal or at least one clock signal derived from the at least one second clock signal, by the at least one of the plurality of sequential logic cells; wherein in the second mode the at least one second clock signal is adapted to the at least one of the plurality of sequential logic cells to generate in at least a portion of the integrated circuit device a current consumption when the at least one first clock signal is not a toggling signal.

And the method may comprise providing 58 a temperature measurement of the integrated circuit device; and switching 60 the integrated circuit device from the second mode into the first mode when a value of the temperature measurement is above a threshold value 62 corresponding to a minimum normal operation temperature.

The method may also comprise switching 64 the integrated circuit device from the first mode into the second mode when a value of the temperature measurement is below the threshold value.

The method may start 49 either in first mode (mode=1) or second mode (mode=2). After executing the stage of providing a temperature measurement, the measured temperature T may be compared with a pre-defined threshold value Tₜₕ. If in block 62 the temperature is found not to be in the normal operation range, the integrated circuit device may be switched 64 into the second mode after a comparison 68, whether the mode is already set to the second mode (mode=2). In the second mode or self-heating mode the providing 52 at least one second clock signal and the receiving 56 the at least one second clock signal or at least one clock signal derived from the at least one second clock signal may be performed.

If T is found to be in the normal operation range (T>Tₜₕ) in block 62, the integrated circuit device may be switched 60 from the second mode into the first mode after a comparison, whether the mode is already set to the first mode (mode=1). In the first mode or normal operation mode the providing 50 at least one first clock signal and the receiving 54 the at least one first clock signal or at least one clock signal derived from the at least one first clock signal may be performed.

In at least one of the embodiments of the method, the temperature may be measured again or continuously, e.g., after entering the normal operation mode after performing the self-heating. In another embodiment, the second clock signal source may be disabled after T is found to be greater than Tₜₕ.

In the foregoing specification, the invention has been described with reference to specific examples of embodiments of the invention. It will, however, be evident that various modifications and changes may be made therein without departing from the broader spirit and scope of the invention as set forth in the appended claims.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein can be designed as either negative or positive logic signals. Therefore, in alternate embodiments, those signals described as positive logic signals may be implemented as negative logic signals, and those signals described as negative logic signals may be implemented as positive logic signals. For example, the reset signal may be of positive or negative polarity, but its purpose is to pre-set (set or clear) the node that is intended to be reset, to the predefined logic value.

Furthermore, the terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality. For example, the mode controller unit 46 and the multiplexer unit 48 may be provided as a single unit.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. For example, the first and second clock signal sources 12, 14 may be located on the same device. Alternatively, the examples may be implemented as any number of separate integrated circuits or separate devices interconnected with each other in a suitable manner. For example, the first clock signal source 12 may be provided as a separate IC.

Also for example, the examples, or portions thereof, may implemented as soft or code representations of physical circuitry or of logical representations convertible into physical circuitry, such as in a hardware description language of any appropriate type.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While the principles of the invention have been described above in connection with specific apparatus, it is to be clearly understood that this description is made only by way of example and not as a limitation on the scope of the invention.

1. An integrated circuit device, comprising
a first clock signal source, arranged to provide at least one first clock signal;
a second clock signal source, arranged to provide at least one second clock signal; and
a plurality of sequential logic cells, at least one of said plurality connected to receive, in a first mode, said at least one first clock signal or at least one clock signal derived from said at least one first clock signal, and to receive, in a second mode, said at least one second clock signal or at least one clock signal derived from said at least one second clock signal; wherein in said second mode said at least one second clock signal is adapted to said at least one of said plurality of sequential logic cells to generate in at least a portion of said integrated circuit device a current consumption when said at least one first clock signal is not a toggling signal.

2. The integrated circuit device as claimed in claim 1, wherein said portion of said integrated circuit device comprises said at least one of said plurality of sequential logic cells.

3. The integrated circuit device as claimed in claim 1, comprising a clock distribution network having at least one input terminal connected to said first and second clock signal sources, and at least one output terminal connected to said plurality of sequential logic cells; said clock distribution network being arranged to receive said at least one first clock signal in said first mode and said at least one second clock signal in said second mode and to provide said at least one first clock signal or said at least one clock signal derived from said at least one first clock signal in said first mode, and to provide said at least one second clock signal or said at least one clock signal derived from said at least one second clock signal in said second mode.

4. The integrated circuit device as claimed in claim 3, wherein said portion of said integrated circuit device comprises at least a part of said clock distribution network.

5. The integrated circuit device as claimed in claim 1, wherein said at least one of said plurality of sequential logic cells comprises a reset-input arranged to receive a reset signal; and wherein said reset signal is enabled when said integrated circuit device is in said second mode.

6. The integrated circuit device as claimed in claim 1, wherein a clock rate of at least one second clock signal is higher than a clock rate of said at least one first clock signal.

7. The integrated circuit device as claimed in claim 1, wherein said second clock source comprises a first ring oscillator circuit.

8. The integrated circuit device as claimed in claim 1, wherein said at least one second clock signal is a steady-state signal.

9. The integrated circuit device as claimed in claim 1, comprising
a temperature sensing unit arranged to provide a temperature measurement of said integrated circuit device; and
a mode controller unit arranged to switch said integrated circuit device from said second mode into said first mode when a value of said temperature measurement is above a threshold value corresponding to a minimum normal operation temperature.

10. The integrated circuit device as claimed in claim 9, wherein said minimum normal operation temperature is defined to at least partly compensate for a switching delay caused by a temperature inversion effect encountered at one or more field-effect transistor circuits comprised in said plurality of sequential logic cells.

11. The integrated circuit device as claimed in claim 9, wherein said mode controller unit is arranged to switch said integrated circuit device from said first mode into said second mode when a value of said temperature measurement is below said threshold value.

12. The integrated circuit device as claimed in claim 9, wherein said temperature sensing unit comprises a second ring oscillator circuit.

13. A method for self-heating an integrated circuit device, comprising
providing at least one first clock signal, by a first clock signal source;
providing at least one second clock signal, by a second clock signal source;
receiving, in a first mode, said at least one first clock signal or at least one clock signal derived from said at least one first clock signal, by at least one of a plurality of sequential logic cells; and
receiving, in a second mode, said at least one second clock signal or at least one clock signal derived from said at least one second clock signal, by said at least one of said plurality of sequential logic cells; wherein in said second mode said at least one second clock signal is adapted to said at least one of said plurality of sequential logic cells to generate in at least a portion of said integrated circuit device a current consumption when said at least one first clock signal is not a toggling signal.

14. The method as claimed in claim 13, comprising
providing a temperature measurement of said integrated circuit device; and
switching said integrated circuit device from said second mode into said first mode when a value of said temperature measurement is above a threshold value corresponding to a minimum normal operation temperature.
